(19) United States
(12) Patent Application Publication
(10) Pub. No.: US 2018/0050959 A1
(43) Pub. Date: Feb. 22, 2018

(54) FABRICATION OF NANOSTRUCTURES IN AND ON ORGANIC AND INORGANIC SUBSTRATES USING MEDIATING LAYERS

(71) Applicant: Max-Planck-Gesellschaft zur Foerderung der Wissenschaften e.V., Muenchen (DE)

(72) Inventors: Jan-Henning DIRKS, Bremen (DE); Wenwen CHEN, Stuttgart (DE); Joachim P. SPATZ, Stuttgart (DE); Robert BRUNNER, Jena (DE); Matthias KRAUS, Jena (DE)

(21) Appl. No.: 15/561,011

(22) PCT Filed: Mar. 24, 2015
(86) PCT No.: PCT/EP2015/000632

§ 371 Date: Sep. 22, 2017

(51) Int. Cl. C03C 17/34; G03F 7/00; C23C 16/02; G02B 1/11

(52) U.S. Cl. CPC C03C 17/34; G03F 7/001; B82Y 20/00; G02B 1/11; C23C 16/0245

(57) ABSTRACT

The present invention relates to a method for creating nanostructures in and on organic or inorganic substrates comprising at least the following steps: a) providing a primary substrate having a predetermined refractive index; b) coating the primary substrate with one or more mediating layers each having a predetermined refractive index different from that of the primary substrate, wherein the sequence of the layers is arranged so that a predetermined gradient of the refractive index is generated between the primary substrate and the uppermost layer of the one or more mediating layers; c) optionally coating the uppermost layer of the one or more mediating layers with an additional top layer; d) depositing a nanostructured etching mask onto the uppermost layer of the composite substrate obtained after steps a)-b) or a)-c); e) generating protruding structures, in particular conical or pillar structures, or recessed structures, in particular holes, in at least the uppermost layer of the composite substrate by means of reactive ion etching. A further aspect of the invention relates to a composite substrate with a nanostructured surface obtainable by said method.

Several methods for generating nanostructures on various substrate surfaces are known in the art. Such nanostructures may be, e.g., used for immobilizing target entities such as biomolecules or for providing antireflective coatings on the respective substrates.

One approach for generating nanostructures or nanopatterns on substrate surfaces is based on electron beam lithography. Typically, however, this methodology is rather slow and costly.

Another commonly used approach involves various etching techniques, including reactive ion etching (RIE), reactive ion beam etching (RIBE), plasma processes etc.

In particular, an especially advantageous method for providing antireflective structures, so called moth-eye structures (MOES), on quartz glass by means of a combination of block copolymer micellar nanolithography (BCML) and RIE has been developed (see, e.g. WO 2008/116616 A1).

However, these methods are often limited with respect to suitable substrate materials and applications. For example, a number of highly refractive substrates such as SF10 glass, CaF₂, Al₂O₃, are difficult or impossible to etch using said combination of BCML and RIE because the BCML mask and the substrates have similar etching rates and/or the etching parameters of the RIE treatment are unsuited for the desired substrate material.

In order to provide non-etchable primary substrates with such nanostructures, it is known to coat the primary substrate with an additional etchable material (such as silica) and to generate the desired nanostructures therein. Typically, however, the refractive index of these etchable layers differs from that of the refractive index of the primary substrate. This results in a considerable decrease of the antireflective properties of the nanostructured substrate. Further, the additional etchable layers tend to be mechanically instable and separate from the primary substrate under some conditions (mechanical or thermal stress).

It was therefore an object of the present invention to provide nanostructures, in particular antireflective nanostructures, in and on a variety of organic and inorganic substrates, including substrate surfaces which were not amenable to conventional etching techniques, and the corresponding nanostructured substrates which overcome the above drawbacks of the prior art.

This object is achieved according to the invention with the provision of the method according to Claim 1 and the composite substrate according to Claim 14. Specific or preferred embodiments and aspects of the invention are the subject matter of the further claims.

### DESCRIPTION OF THE INVENTION

The method according to the invention for creating nanostructures in and on organic or inorganic substrates according to Claim 1 comprises at least the following steps:
a)providing a primary substrate having a predetermined refractive index;
b) coating the primary substrate with one or more (preferably a plurality of) mediating layers each having a predetermined refractive index different from that of the primary substrate, wherein the sequence of the layers is arranged so that a predetermined gradient of the refractive index is generated between the primary substrate and the uppermost layer of the one or more mediating layers;
c) optionally coating the uppermost layer of the one or more mediating layers with an additional top layer;
d) depositing a nanostructured etching mask onto the uppermost layer of the composite substrate obtained after steps a)-b) or a)-c);
e) generating protruding structures, in particular conical or pillar structures, or recessed structures, in particular holes, in at least the uppermost layer of the composite substrate by means of reactive ion etching.

In a specific embodiment of the method according to the present invention, the nanostructured etching mask comprises an ordered array of nanoparticles or statistically distributed nanoparticles in which the spatial frequencies of the statistical distribution shows only contributions which are larger than the inverse of the wavelength of light (typically from 30 nm to 300 nm).

In a preferred embodiment of the invention, an ordered array of nanoparticles is provided on the substrate surface by means of a micellar diblock copolymer nanolithography technology, as described e.g. in EP 1 027 157 B1 and DE 197 47 815 A1. In micellar nanolithography, a micellar solution of a block copolymer is deposited onto a substrate, e.g. by means of dip coating, and under suitable conditions forms an ordered film structure of chemically different polymer domains on the surface, which inter alia depends on the type, molecular weight and concentration of the block copolymer. The micelles in the solution can be loaded with inorganic salts which, following deposition with the polymer film, can be oxidized or reduced to inorganic nanoparticles. A further development of this technology, described in the patent application DE 10 2007 017 032 A1, enables to two-dimensionally set both the lateral separation length of the polymer domains mentioned and thus also of the resulting nanoparticles and the size of these nanoparticles by means of various measures so precisely that nanostructured surfaces with desired spacing and/or size gradients can be manufactured. Typically, nanoparticle arrangements manufactured with such a micellar nanolithography technology have a quasi-hexagonal pattern.

The BCML etching mask may be deposited on the primary substrate by any suitable method known in the art such as, e.g., dip coating or spin coating.

Principally, the material of the nanoparticles is not particularly limited and can comprise any material known in the prior art for such nanoparticles. Typically, this is a metal or metal oxide. A broad spectrum of suitable materials is mentioned in DE 10 2007 014 538 A1. Preferably, the material of the metal or the metal component of the nanoparticles is selected from the group made up of Au, Pt, Pd, Ag, In, Fe, Zr, Al, Co, Ni, Ga, Sn, Zn, Ti, Si and Ge, mixtures and composites thereof. Specific examples for a preferred metal oxide are titanium oxide, iron oxide and cobalt oxide. Preferred examples for a metal are gold, palladium and platinum and gold is particularly preferred.

The term “particle” as used here also comprises a “cluster”, particularly as described and defined in DE 10 2007 014 538 A1 and DE 197 47 815 A1 and both terms can be used here interchangeably.

Advantageously, the material of the primary substrate is not especially limited and may be selected from a wide range of organic and inorganic substrates.

In one specific embodiment, the material of the primary substrate is selected from glasses, in particular comprising one of the following base systems of inorganic glasses with their main components: 1) B₂O₃—La₂O₃—MₘOₙ (m being an integer from 1 to 2 and n being an integer from 2 to 5; MₘOₙ preferably selected from ZrO₂, Ta₂O₅, Nb₂O₅, Gd₂O₃, Y₂O₃, TiO₂, WO₃) ; 2) (B₂O₃, SiO₂)—La₂O₃—MO, MO being a metal oxide typically selected from MgO, CaO, SrO, BaO, ZnO; 3) SiO₂—PbO—M₂O with (for example) M₂O selected from Li₂O, Na₂O, K₂O, Ca₂O; the PbO content in glasses of the system SiO₂—PbO—M₂O can be replaced partially or completely by TiO₂; 4) SiO₂—B₂O₃—BaO; 5) (SiO₂, B₂O₃)—BaO—PbO; 6) SiO₂—M₂O—TiO₂ (preferably the glass lattice/matrix comprises additional molecules, atoms, or ions of fluorine (e.g. F₂) and/or oxygen) with M₂O being a metal oxide typically selected from Li₂O, Na₂O, K₂O, Ca₂O; 7) P₂O₅—Al₂O₃—MO—B₂O₃ with (for example) MO selected from: MgO, CaO, SrO, BaO, ZnO; 8) SiO₂—BaO—M₂O with (for example) M₂O selected from Li₂O, Na₂O, K₂O, Ca₂O.

In more specific embodiments, the material of the primary substrate comprises or consists of glasses and quartz glasses, in particular SF10, N-LASF 9 (Schott, refractive index 1.85), N-LASF 45 Schott, refractive index 1.80), N-SF6 (Schott, refractive index 1.81, N-SF57 (Schott, refractive index 1.85), S-LAM 66 (Ohara, refractive index 1.80), S-TIH14 (Ohara, refractive index 1.76), S-BAH28 (Ohara, refractive index 1.72), NBF1 (Hoya, refractive index 1.74), NBFD3 (Hoya, refractive index 1.81), or E-FD8 (Hoya, refractive index 1.69) glass, SiO₂, CaF₂, GaAs, Al₂O₃.

In preferred embodiments, the material of the primary substrate is selected from quartz glasses, in particular high quality quarz glasses, such as suprasil glass.

In another specific embodiment, the material of the primary substrate is selected from organic materials such as polymethylmethacrylate (PMMA), polycarbonate (PC), polycarbonate-comprising copolymers (e.g. PC-HT), styrene-methylmethacrylate-copolymer (SMMA), methacryl-acrylnitrile-butadien-styrene-copolymer (MABS), polystyrene (PS), styrene-acrylnitrile-copolymer (SAN), polymethacrylmethylimide (PMMI), cycloolefin-based polymers (COP), cycloolefin-based copolymers (COC), polyethersulfones (PES), polyetherimides (PEI), polmethylenepentene (TPX), polyamide 12 (PA 12), allyldiglycol-carbonate.

The material of each of the one or more mediating layers, preferably of a plurality of mediating layers, is selected such that a desired gradient of the refractive index is generated between the primary substrate and the uppermost layer of the intermediate layers.

In a specific embodiment of the invention, the material of the one or more mediating layers is selected from the group comprising glass and quartz glass, in particular SiOx (with 1<x<2) and SiOxNy (with 1<x<2 and y/x+y in the range from 0 to 0.5 and with N/(N+O) from 0% to 50%).

The thickness of the one or more mediating layer(s) is not especially limited and may be adjusted as appropriate for the respective substrate and coating materials and applications.

For optical applications, such as antireflective lenses, mediating layers having a total thickness in the range from 200 to 500 nm may be typically used.

The mediating layers typically are deposited by reactive pulse sputtering using a magnetron system from a silicon target. Argon can be used as inert gas and a mixture of oxygen and nitrogen as reactive gas. The mediating layers are formed by continuously adapting the ratio of the mixture of oxygen and nitrogen. The deposition of the layers typically starts from the refractive index of the substrate glass and is decreased down to that of the top layer, typically SiO₂.

Typically, the nanostructures created by one or more etching treatments are conical or pillar-shaped structures. The height of the structures typically lies in a range of 50 nm to 400 nm, preferably of 150 nm to 300, and typically they have a diameter in the range of 5 nm to 50 nm, preferably of 10 nm to 30 nm, (measured in half height of the structures).

In a typical embodiment, the refractive index of the primary substrate is in the range from 1.46 to 2.01, more typically in the range from 1.6 to 1.9, and the refractive index of the uppermost layer of the composite substrate obtained after steps a)-b) or a)-c) above is in the range from 1.3 to 1.6., typically in the range of SiO₂.

The material of the optional additional top layer may be identical with or different from the material of the mediating layer(s). In the first case, the material of the additional top layer may be selected from the group comprising quartz glass, such as SiO₂and SiOxNy (with x and y as defined above), with N/(N+O) from 0% to 50%.

In any case, the additional top layer does not contribute to the gradient of the refractive index generated by the layers below, thus its refractive index will ideally be identical with the uppermost layer of the intermediate layers.

The thickness of the top layer may in the range from 50 to 1200 nm.

Suitable methods for plasma etching or reactive ion etching are principally known in the art (see, e.g. DE 10 2007 014 538 A1 and Lohmüller et al. (NANO LETTERS 2008, Vol. 8, No. 5, 1429-1433).

The etching step e) can comprise one or several treatments with the same etching agent and/or with different etching agents. The etchant can basically be any etchant known in the prior art and suitable for the respective substrate surface. Preferably, the etchant is selected from the group of chlorine gases, e.g. Cl₂, BCl₃ and other gaseous chlorine compounds, fluorinated hydrocarbons, e.g. CHF₃, CH₂F₂, CH₃F, fluorocarbons, e.g. CF₄, C₂F₈, oxygen, argon, SF₆ and mixtures thereof.

Preferably, the etching comprises at least one treatment with a mixture of Ar/SF₆/O₂ or Ar/SF₆ as etchant and at least one treatment with a mixture of Ar/CHF₃ as etchant.

For example, a combination of a first etching step with a mixture of Ar/SF₆ as etchant and a second etching step with a mixture of Ar/SF₆/O₂ may be used to produce pillar-shaped nanostructures from a SiOx substrate. A combination of a first etching step with a mixture of Ar/SF₆/O₂ and a second etching step with a mixture of Ar/CHF₃ may be used to produce conical nanostructures from a SiOx substrate.

Typically, each etching step is carried out for a period in the range of 5 s or 10 s to 10 min, preferably in the range from 10 s to 60 s.

The duration of the entire etching treatment typically lies in the range of 10 s to 60 minutes, preferably 1 to 15 minutes.

Typically, the obtained nanostructures have a diameter in the range of 10-100 nm, preferably 10-30 nm, and a height of 10-800 nm, preferably 250-500 nm. In the case of conical structures, the diameter data refer to the thickness at half height. The average spacings of the nanostructures are preferably in a range from 15 to 250 nm.

For some applications it is preferred that the nanoparticles used as an etching mask have a predetermined two-dimensional geometric arrangement on the substrate surface. Such arrangement has predetermined minimum or average particle spacings as a characteristic, wherein these predetermined particle spacings can be the same in all regions of the substrate surface or various regions can have different predetermined particle spacings. A geometric arrangement of this type can fundamentally be realized with any suitable method of the prior art, micellar nanolithography in particular, as explained in more detail above.

Some embodiments of the method according to the present invention involve at least one further processing step of a mechanical treatment, such as sonication, of the protruding structures generated in the course of the etching step.

In a specific embodiment of the present invention, the structures generated in the top layer and/or the mediating layer(s) of the composite substrate are used as an etching mask and protruding structures corresponding to the protruding structures of the layer (s) above are generated in the primary substrate and the layer (s) above the primary substrate are removed in part or completely.

This further etching treatment may be accomplished by means of reactive ion beam etching (RIBE), chemically assisted ion beam etching (CAIBE), reactive ion etching (RIE) or inductive coupled plasma (RIE-ICP) as appropriate for the respective substrate layer.

Using the above multi-step-etching process enables to achieve nanostructures on or in the primary substrate which were not obtainable by a direct etching treatment of the primary substrate.

A nanostructured primary substrate which is free from any coating layers (mediating layers and optionally a top layer) is mechanically more stable, since no coating layers are potentially detachable under conditions of mechanical or thermal stress. Also, if the coating layers are completely removed in the final etching step, it is possible to use toxic or nonbiocompatible intermediate layers and still obtain a biocompatible final product. This allows more flexibility in conducting the method of the invention.

In a preferred embodiment of the invention, the composite substrate obtained by the method as outlined above is an optical element and the structures generated form an anti-reflective surface structure on the optical element.

A further aspect of the present invention relates to the nanostructured composite substrate obtainable by the method as outlined above.

Typically, the composite substrate with a nanostructured surface according to the present invention comprises a primary substrate having a defined refractive index, preferably in the range from 1.3 to 2.1; one or more (preferably a plurality of) mediating layers having a predetermined refractive index different from that of the primary substrate wherein the sequence of the layers is arranged so that a defined gradient of the refractive index is provided between the primary substrate and the uppermost layer of the one or more mediating layer; optionally an additional top layer; and nanostructures, in particular conical or pillar structures, on the surface of the composite substrate, which structures are composed of the material of the additional top layer of the composite substrate (optionally capped with nanoparticles) and/or the material of the one or more mediating layers.

In a more specific embodiment of said composite substrate, the protruding structures further comprise of material of the primary substrate.

Preferably, the nanostructured composite substrate or primary substrate is an optical element and the protruding structures form an anti-reflective surface structure on the optical element.

In a more specific embodiment of said composite substrate or optical element, the protruding structures have a predetermined two-dimensional geometric arrangement, in particular a hexagonal arrangement, or are statistically distributed such that the spatial frequencies of the statistical distribution shows only contributions which are larger than the inverse of the wavelength of light (typically in a range from 30 nm to 300 nm).

In one specific embodiment, the material of the primary substrate is selected from glasses, in particular comprising one of the following base systems of inorganic glasses with their main components: 1) B₂O₃—La₂O₃—MₘOₙ (m being an integer from 1 to 2 and n being an integer from 2 to 5; MₘOₙ preferably selected from ZrO₂, Ta₂O₅, Nb₂O₅, Gd₂O₃, Y₂O₃, TiO₂, WO₃) ; 2) (B₂O₃, SiO₂)—La₂O₃—MO, MO being a metal oxide typically selected from MgO, CaO, SrO, BaO, ZnO; 3) SiO₂—PbO—M₂O with (for example) M₂O selected from Li₂O, Na₂O, K₂O, Ca₂O; the PbO content in glasses of the system SiO₂—PbO—M₂O can be replaced partially or completely by TiO₂; 4) SiO₂—B₂O₃—BaO; 5) (SiO₂, B₂O₃)—BaO—PbO; 6) SiO₂—M₂O—TiO₂ (preferably the glass lattice/matrix comprises or is doped with additional molecules, atoms, or ions of fluorine and/or oxygen) with M₂O being a metal oxide typically selected from Li₂O, Na₂O, K₂O, Ca₂O; 7) P₂O₅—Al₂O₃—MO—B₂O₃ with (for example) MO selected from: MgO, CaO, SrO, BaO, ZnO; 8) SiO₂—BaO—M₂O with (for example) M₂O selected from Li₂O, Na₂O, K₂O, Ca₂O.

In more specific embodiments, the material of the primary substrate comprises or consists of glasses and quartz glasses, in particular SF10, N-LASF 9 (Schott, refractive index 1.85), N-LASF 45 Schott, refractive index 1.80), N-SF6 (Schott, refractive index 1.81, N-SF57 (Schott, refractive index 1.85), S-LAM 66 (Ohara, refractive index 1.80), S-TIH14 (Ohara, refractive index 1.76), S-BAH28 (Ohara, refractive index 1.72), NBF1 (Hoya, refractive index 1.74), NBFD3 (Hoya, refractive index 1.81), or E-FD8 (Hoya, refractive index 1.69) glass, SiO₂, CaF₂, GaAs, Al₂O₃.

In preferred embodiments, the material of the primary substrate is selected from quartz glasses, in particular high quality quarz glasses, such as suprasil glass.

In another specific embodiment, the material of the primary substrate is selected from organic materials such as polymethylmethacrylate (PMMA), polycarbonate (PC), polycarbonate-comprising copolymers (e.g. PC-HT), styrene-methylmethacrylate-copolymer (SMMA), methacryl-acrylnitrile-butadien-styrene-copolymer (MABS), polystyrene (PS), styrene-acrylnitrile-copolymer (SAN), polymethacrylmethylimide (PMMI), cycloolefin-based polymers (COP), cycloolefin-based copolymers (COC), polyethersulfones (PES), polyetherimides (PEI), polmethylenepentene (TPX), polyamide 12 (PA 12), allyldiglycol-carbonate.

Preferably, the material of the one or more mediating layers of the composite material is selected from the group comprising glass, in particular SiOx and SiOxNy, SiOx (with 1<x<2) and SiOxNy (with y/x+y in the range from 0 to 0.5 and N/(N+O) from 0% to 50%).

Also, the material of the additional top layer, if any, is preferably selected from the group comprising quartz glass, such as SiO₂ and SiOxNy, SiOx (with 1<x<2) and SiOxNy, with x and y as defined above and N/(N+O) from 0% to 50%.

The products of the method according to the invention offer a wide range of application options in the fields of semiconductor technology, optics, sensor technology and photovoltaics.

A few non-limiting examples for this are the use in optical devices, particularly optical elements such as lenses, diffraction gratings and other refracting or diffractive structures, sensors, particularly CCD sensors and solar cells.

A particularly preferred application relates to the use in optical elements, particularly for minimizing reflection.

### BRIEF DESCRIPTION OF THE FIGURES

FIG. 1 schematically shows the main steps of the method according to the invention for preparing a nanostructured composite substrate or primary substrate.

FIG. 2 schematically shows the gradient of the refractive index formed by the primary substrate and the overlaid mediating layers.

FIG. 3 shows the data of transmission measurements performed on a plain SF10 substrate, a GRIN-coated SF10 substrate and a SF10 substrate coated with GRIN and an additional layer of MOES. The optical characterisation of plain, GRIN and MOES+GRIN substrates shows that the transmission of MOES+GRIN structured substrates is superior compared to the transmission of GRIN-structured surfaces alone.

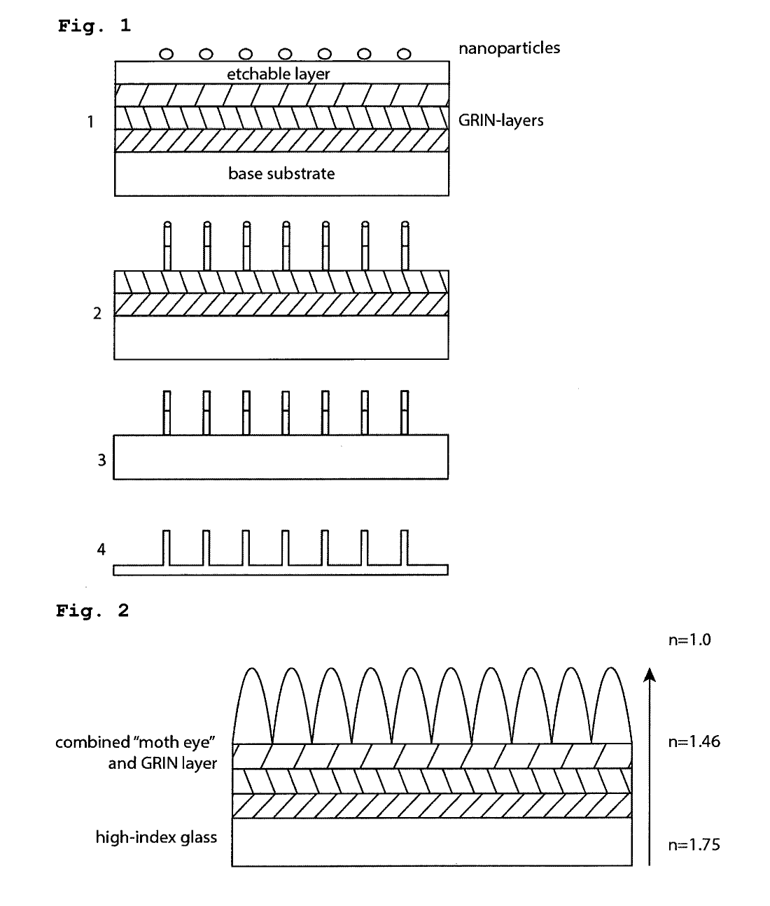

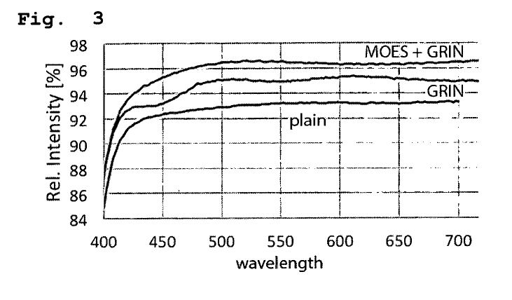

The following examples are used for more in depth explanation of the present invention, without limiting the same thereto, however. It will be evident for the person skilled in the art that variations of these conditions in dependence of the specific materials used may be required and can be determined without difficulty by means of routine experiments.

### EXAMPLE 1

### Creation of Nanostructures on a Composite Substrate

### 1. Providing a Composite Substrate

A primary substrate of SF10 glass is coated with several intermediate layers of amorphous SiₓO_{y}N_{z} forming a gradient of refractive indices (GRIN). The indices x, y and z of each intermediate layer are selected to provide a desired refractive index difference to the underlying layer. The GRIN layers are deposited by reactive pulse sputtering using a magnetron system from a silicon target. Argon was used as inert gas and a mixture of oxygen and nitrogen as reactive gas.

The layered structure of the GRIN-layer is formed by continuously adapting the ratio of the mixture of oxygen and nitrogen. The deposition of the GRIN profile is starting from the refractive index of the base substrate (SF10) and is decreased down to that of the covering SiO₂ layer, forming the composite substrate consisting of SF10 (base), GRIN layer and a top SiO₂ layer.

### 2. Providing an Array of Nanoparticles on the Substrate Surface

The surface of the uppermost layer of the composite substrate was coated with gold nanoparticles in a defined arrangement by means of micellar nanolithography. In this step, one of the protocols described in EP 1 027 157 B1, DE 197 47 815 A1 or DE 10 2007 017 032 A1 can be followed. The method involves the deposition of a micellar solution of a block copolymer (e.g. polystyrene(n)-b-poly(2-vinylpyridine(m)) in toluene) onto the substrate, e.g. by means of dip or spin coating, as a result of which an ordered film structure of polymer domains is formed on the surface. The micelles in the solution are loaded with a gold salt, preferably HAuCl₄, which, following deposition with the polymer film, can be reduced to the gold nanoparticles.

The reduction can take place chemically, e.g. with hydrazine, or by means of energy-rich radiation, such as electron radiation or light. Optionally, after or at the same time as the reduction, the polymer film can be removed (e.g. by means of plasma etching with Ar-, H- or O-ions) . Thereafter, the substrate surface is covered with an arrangement of gold nanoparticles.

### 3. First Etching

Subsequently, the etching of the substrate surface covered with gold nanoparticles took place in a desired depth. A “reactive ion etcher” from Oxford Plasma, device: PlasmaLab 80 plus was used to this end. Other devices known in the prior art are likewise fundamentally suitable, however. The etching consisted of two treatment steps with various etchants which were carried out several times one after the other.

The following protocol was used to create conical nanostructures:

### Step 1;

A mixture of Ar/SF₆/O₂ in the ratio 10:40:8 (sccm) was used as etchant (process gas).
Pressure: 50 mTorr
RF power: 120 W
ICP power: 0 W
Time: 60 s

### Step 2:

Etchant: Ar/CHF₃:40:40
Pressure: 50 mTorr
RF power: 120 W
ICP power: 20 W
Time: 20 s

These 2 steps were carried out alternately 8 times.

Alternatively, the following protocol was used to create pillar-shaped nanostructures:

### Step 1:

A mixture of Ar/SF₆ in the ratio 40:40 (sccm) was used as etchant (process gas).
Pressure: 50 mTorr
RF power: 120 W
ICP power: 0 W
Time: 60 s

### Step 2:

Etchant: Ar/CHF₃:40:40
Pressure: 50 mTorr
RF power: 120 W
ICP power: 20 W
Time: 20 s

These 2 steps were carried out alternately 8 times.

The total duration of the etching treatment varied depending on the desired depth of the etching within about 1-15 minutes. As a result, column-like or conical nanostructures were obtained, which still can show gold nanoparticles on their upper side.

### 4. Second Etching

The nanostructures created in the mediating layers according to step 3 above can further be used as an etching mask for transferring said nanostructures into the primary substrate layer by means of reactive ion beam etching (RIBE). Compared to the previous RIE process, the RIBE process is less selective and can etch substrates, which cannot be etched using RIE.

Reactive ion beam etching (RIBE) uses an energetic, broad beam collimated and highly directional ion source to physically mill material from a substrate mounted on a rotating fixture with adjustable tilt angle. In contrast to ion beaming (IBE), in the RIBE process reactive ions are incorporated in whole or in part in the etching ion beam.

The ion sources used are “gridded” ion sources, e.g. of the Kaufman type or microwave electron cyclotron resonance (ECR). The etching process involves the control of the ion incident angle and a separate control of the ion flux and ion energy. Typical reactive and inert gases used for RIBE are Ar, N₂, O₂, CHF₃ CF₄ and SF₆.

The RIBE process directly transferred the nanostructure of the mediating layer into the base substrate.

### EXAMPLE 2

### Characterization of Nanostructured Composite or Primary Substrates

To illustrate the superior optical properties of the MOES+GRIN substrates, a plain SF10 surface, a GRIN coated SF10 surface and a single-sided MOES+GRIN coated surface were optically characterized using a spectrometer.

Compared to the plain SF10 substrate, the MOES+GRIN substrate shows a notably improved transmission, which covers a wide rage of wavelengths, as typical for MOES structures (see FIG. 3).

1. A method for producing nanostructures in and on organic or inorganic substrates comprising at least the following steps:
a) providing a primary substrate having a predetermined refractive index;
b) coating the primary substrate with one or more mediating layers each having a predetermined refractive index different from that of the primary substrate, wherein a sequence of the layers is arranged so that a predetermined gradient of the refractive index is generated between the primary substrate and an uppermost layer of the one or more mediating layers;
c) optionally coating the uppermost layer of the one or more mediating layers with an additional top layer;
d) depositing a nanostructured etching mask onto the uppermost layer of a composite substrate obtained after steps a)-b) or a)-c); and
e) generating protruding structures, or recessed structures in at least the uppermost layer of the composite substrate by reactive ion etching.

2. The method according to claim 1, wherein the nanostructured etching mask comprises an ordered array of nanoparticles or statistically distributed nanoparticles in which spatial frequencies of a statistical distribution shows only contributions which are larger than an inverse of the wavelength of light.

3. The method according to claim 2, wherein the ordered array of nanoparticles forming the etching mask is provided by micellar diblock or multiblock copolymer nanolithography.

4. The method according to claim 1, wherein the primary substrate comprises a material selected from the group consisting of quartz glasses and glasses.

5. The method according to claim 1, wherein the one or more mediating layers comprises a material selected from the group consisting of glass and quartz glass.

6. The method according to claim 1, wherein the additional top layer comprises a quartz glass material.

7. The method according to claim 1, wherein the refractive index of the primary substrate is in a range from 1.46 to 2.01 and the refractive index of the uppermost layer of the composite substrate is in a range from 1.3 to 1.6.

8. The method according to claim 1, wherein the etching comprises at least one treatment with an etchant which is selected from the group consisting of chlorine, gaseous chlorine compounds, fluorinated hydrocarbons, fluorocarbons, oxygen, argon, SF₆ and mixtures thereof.

9. The method according to claim 8, wherein the etching comprises at least one treatment with a mixture of Ar/SF₆/O₂ or Ar/SF6 as the etchant and at least one treatment with a mixture of Ar/CHF₃ as the etchant.

10. The method according to claim 1, wherein each etching treatment is carried out for a period in a range of 10 s to 10 min.

11. The method according to claim 1 which further comprises a mechanical treatment of the protruding structures generated.

12. The method according to claim 1 which comprises a further etching treatment by means of reactive ion beam etching (RIBE), chemically assisted ion beam etching (CAIBE), reactive ion etching (RIE) or inductive coupled plasma (RIE-ICP), wherein the structures generated in the top layer and/or the one or more mediating layers of the composite substrate are used as an etching mask and protruding structures corresponding to the protruding structures of layer(s) above are generated in the primary substrate and layer(s) above the primary substrate are removed in part or completely.

13. The method according to claim 1, wherein the composite substrate is an optical element and the structures generated form an anti-reflective surface structure on the optical element.

14. A composite substrate with a nanostructured surface comprising
a primary substrate having a defined refractive index;
one or more mediating layers having a predetermined refractive index different from that of the primary substrate wherein a sequence of the layers is arranged so that a defined gradient of the refractive index is provided between the primary substrate and an uppermost layer of the one or more mediating layers;
optionally an additional top layer; and
nanostructures on the surface of the composite substrate, which nanostructures are composed of a material of the additional top layer of the composite substrate and/or a material of the one or more mediating layers.

15. The composite substrate according to claim 14, wherein the nanostructures comprise protruding structures further comprising material of the primary substrate.

16. The composite substrate according to claim 15 which is an optical element and wherein the protruding structures form an anti-reflective surface structure on the optical element.

17. The composite substrate according to claim 15, wherein the protruding structures have a predetermined two-dimensional geometric arrangement, or are statistically distributed such that spatial frequencies of a statistical distribution show only contributions which are larger than an inverse of a wavelength of light.

18. The composite substrate according to claim 15, wherein the primary substrate comprises a material selected from the group consisting of quartz glasses and glasses.

19. The composite substrate according to claim 15, wherein the one or more mediating layers comprises a glass material.

20. The composite substrate according to claim 18, wherein the top layer comprises a quartz glass material.

21. The composite substrate according to claim 15, configured for use in fields selected from the group consisting of semi-conductor technology, optics, sensor technology and photo-voltaics.

22. The composite substrate according to claim 21 configured for use in a member selected from the group consisting of optical devices, sensors, and solar cells.

23. The method according to claim 1, wherein the protruding structures are conical or pillar structures, and the recessed structures are holes.

24. The method according to claim 2, wherein the light is in a range from 30 nm to 300 nm.

25. The method according to claim 4, wherein the material of the primary substrate is a member selected from the group consisting of:
1) B₂O₃—La₂O₃—MₘOₙ (m being an integer from 1 to 2 and n being an integer from 2 to 5);
2) (B₂O₃, SiO₂)—La₂O₃—MO;
3) SiO₂—PbO—M₂O; the PbO content in glasses of the system SiO₂—PbO—M₂O being partially or completely replaceable by TiO₂;
4) SiO₂—B₂O₃—BaO;
5) (SiO₂, B₂O₃)—BaO—PbO;
6) SiO₂—M₂O—TiO₂;
7) P₂O₅—Al₂O₃—MO—B₂O₃; and
8) SiO₂—BaO—M₂O,
where M is a metal.

26. The method according to claim 4, wherein the material of the primary substrate is a member selected from the group consisting of:
1) B₂O₃—La₂O₃—MₘOₙ, where m is an integer from 1 to 2, n is an integer from 2 to 5, and MₘOₙis a member selected from the group consisting of ZrO₂, Ta₂O₅, Nb₂O₅, Gd₂O₃, Y₂O₃, TiO₂ and WO₃;
2) (B₂O₃, SiO₂)—La₂O₃—MO, where MO is a metal oxide selected from the group consisting of MgO, CaO, SrO, BaO and ZnO;
3) SiO₂—PbO—M₂O, where M₂O is a member selected from the group consisting of Li₂O, Na₂O, K₂O and Ca₂O; the PbO content in glasses of the system SiO₂—PbO—M₂O being partially or completely replaceable by TiO₂;
4) SiO₂—B₂O₃—BaO;
5) (SiO₂, B₂O₃)—BaO—PbO;
6) SiO₂—M₂O—TiO₂, comprising additional molecules, atoms, or ions of fluorine and/or oxygen, where M₂O is a metal oxide selected from the group consisting of Li₂O, Na₂O, K₂O and Ca₂O;
7) P₂O₅—Al₂O₃—MO—B₂O₃, where MO is a member selected from the group consisting of MgO, CaO, SrO, BaO and ZnO; and
8) SiO₂—BaO—M₂O, where M₂O is a member selected from the group consisting of Li₂O, Na₂O, K₂O and Ca₂O.

27. The method according to claim 5, wherein the material of the one or more mediating layers is selected from the group consisting of SiOx, where 1<x<2 and SiOxNy, where y/y+x is in a range from 0 to 0.5 and N/(N+O) is from 0% to 50%.

28. The method according to claim 6, wherein the quartz glass material of the additional top layer is a member selected from the group consisting of SiO₂ and SiOxNy, where x and y are 1<x<2, y/y+x is in a range from 0 to 0.5 and N/(N+O) is from 0% to 50%.
